(19) United States
(12) Patent Application Publication
(10) Pub. No.: US 2019/0383874 A1
(43) Pub. Date: Dec. 19, 2019

(54) ALTERNATIVE TECHNIQUES FOR DESIGN OF EXPERIMENTS

(71) Applicants: Holger M. Jaenisch, Toney, AL (US); James W. Handley, Toney, AL (US); Louis J. Gullo, Marana, AZ (US)

(72) Inventors: Holger M. Jaenisch, Toney, AL (US); James W. Handley, Toney, AL (US); Louis J. Gullo, Marana, AZ (US)

(21) Appl. No.: 16/554,206

(22) Filed: Aug. 28, 2019

Related U.S. Application Data
(63) Continuation-in-part of application No. 16/522,235, filed on Jul. 25, 2019.
Application No. 16/522,235 is a continuation-in-part of application No. 16/381,179, filed on Apr. 11, 2019.
Application No. 16/381,179 is a continuation-in-part of application No. 16/297,202, filed on Mar. 8, 2019.
Application No. 16/297,202 is a continuation-in-part of application No. 16/265,526, filed on Feb. 1, 2019.
(60) Provisional application No. 62/694,882, filed on Jul. 6, 2018.
(60) Provisional application No. 62/640,958, filed on Mar. 9, 2018.
(60) Provisional application No. 62/655,564, filed on Apr. 10, 2018.

(51) Int. Cl. G01R 31/3183; G06F 17/50

(52) U.S. Cl. CPC G01R 31/318342; G06F 2217/16; G06F 17/5009

(57) ABSTRACT

Presented herein are alternatives to design of experiments. A method can include sampling a model that explains a measurement corpus of measurement data to generate a sampled model, identifying an invalid region of the sampled model, determining whether a device will operate within the identified invalid region, if the device will operate within the identified invalid region, causing further measurement data to be captured in the identified invalid region, and generating a new model, based only on the further measurement data, to explain device operation within the identified invalid region that augments the sampled model to explain the device behavior.

### RELATED APPLICATIONS

This application is a continuation-in-part of U.S. Utility patent application Ser. No. 16/381,179, filed on Apr. 11, 2019, and titled “Behavior Monitoring Using Convolutional Data Modeling”, U.S. Utility patent application Ser. No. 16/522,235, filed on Jul. 25, 2019, and titled “Improved Gene Expression Programming”, U.S. Utility patent application Ser. No. 16/297,202, filed on Mar. 8, 2019, and titled “Machine Learning Technique Selection and Improvement”, which application claims priority to U.S. Provisional Patent Application Ser. No. 62/694,882, filed on Jul. 6, 2018 and U.S. Provisional Patent Application Ser. No. 62/640,958, filed on Mar. 9, 2018, and this application is a continuation-in-part of U.S. Utility patent application Ser. No. 16/265,526, filed on Feb. 1, 2019, and titled “Device Behavior Anomaly Detection”, which application claims priority to U.S. Provisional Patent Application Ser. No. 62/655,564, filed on Apr. 10, 2018, which are incorporated by reference herein in their entireties.

### TECHNICAL FIELD

Embodiments described herein generally relate to data processing and device design. More specifically, embodiments regard modeling behavior of a theoretical device behavior based on data from other devices. The modelling can help identify critical operational regimes that can be problematic or otherwise can be handled by further device design.

### BACKGROUND

Developers of product are constantly working to identify faults in their devices. A field of study called design of experiments (DOE) is commonly used to help developers identify faults or problematic operational regimes of an existing product. The developer gathers operational data from their product, generates a model of the product, and attempt to identify explanations for the variation in the generated model. An experiment then aims to predict an outcome (change in dependent variables) by introducing a change to an independent variable. The experiment involves selection of suitable independent, dependent, and control variables. However, DOE presumes an already existing device or product. Further, the model used and the analysis using DOE can be less than optimal in terms of explaining the data. Embodiments herein can help overcome one or more drawbacks of the DOE.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings.

FIG. 1 illustrates, by way of example, a diagram of an embodiment of a method for device analysis and verification.

FIG. 2 illustrates, by way of example, a diagram of an embodiment of a system for SV.

FIG. 3 illustrates, by way of example, a diagram of an embodiment of a method for identifying an anomalous behavior.

FIG. 4 illustrates, by way of example, a diagram of an embodiment of an operation of the method of FIG. 3.

FIG. 5 illustrates, by way of example, a diagram of an embodiment of a system for anomaly detection.

FIG. 6 illustrates, by way of example, a diagram of an embodiment of a system for synthetic data generation and model generation.

FIG. 7 illustrates, by way of example, a portion of a synthetic data generation process, such as can be performed by the SV data generator.

FIG. 8 illustrates, by way of example, a diagram of an embodiment of a method for generating and using synthetic data (e.g., for model generation).

FIG. 9 illustrates, by way of example, a diagram of an embodiment of a method for generating synthetic data.

FIG. 10 illustrates, by way of example, a diagram of an embodiment of a flow chart for an odometer method for generating a complete polynomial of a specified order.

FIG. 11 illustrates, by way of example, a diagram of an embodiment of the operations of the method.

FIG. 12 illustrates, by way of example, a flow chart of an embodiment of a method of data modeling.

FIG. 13 illustrates a flow chart of a method for generating the Handley differential operator, such as can be used for behavior monitoring.

FIG. 14 illustrates, by way of example, a diagram of an embodiment of a system for gene expression programming (GEP) model generation.

FIG. 15 illustrates, by way of example, a diagram of an embodiment of a GEP modeling method.

FIG. 16 illustrates, by way of example, a diagram of an embodiment of a method for determining a value that governs genetic alteration.

FIG. 17 illustrates, by way of example, a graph of model predictions and a variable to be predicted by the model.

FIG. 18 illustrates, by way of example, a diagram of an embodiment of a graph of a sampled model.

FIG. 19 illustrates, by way of example, a diagram of an embodiment of an alternative method to DOE.

FIG. 20 illustrates, by way of example, a block diagram of an embodiment of a machine on which one or more of the methods, such as those discussed about FIGS. 1-19 and elsewhere herein can be implemented.

### DETAILED DESCRIPTION

Aspects of the embodiments are directed to systems, methods, computer-readable media, and means for modeling a potential device, identifying operational regimes that may be problematic, and/or adjusting design of the potential device to operate such that an operational regime is less problematic.

Embodiments can obtain data of measurements and target objectives from which to make inferences. The data can be from a previous generation of a device, other related devices, a device that includes a same or similar system to be used in a new device, or the like. There are many data sources and embodiments are not limited to data from a specific data source. Embodiments can use data in text form, graphic form, or the like. Embodiments can convert data in graphic form to text form for processing.

The obtained measurements can be thinned to a minimum relevant subset of the measurement data. The data in the minimum relevant subset can be information bearing and relevant. The subset can be determined by a spatial voting (SV) process. Synthetic data can be generated to further reduce the minimum relevant subset without losing relevant information. A model can be derived based on the minimum relevant subset of data. A gene expression programming (GEP) technique can be used to generate the model or a complete polynomial model can be generated using a convolutional data process.

The model can then be analyzed to determine boundaries thereof and identify where the model becomes fragmented rather than smooth and continuous. More data can be gathered to help improve the regions of the model in or near which the model becomes more fragmented and the process of generating the model can be repeated. If data is received and mapped to an operational region in which the model is not relevant, another model can be generated for the operational region, such as by using a same process. The unexplainable residuals of the inferred states translates into the actual confidence of accurately explaining the current state based on the known environmental indicators. The confidence can feed physics of failure models for your failure prediction or remaining useful life (RUL).

7—Finally ITM based approximations to Physics of Failure published models can be derived to be customized to this use case and further improve the failure predictive accuracy.

In the prior DOE, a model is learned via curve fitting, such as curve fitting derivatives as is used in machine learning (ML) techniques (e.g., neural network (NN), logistic regression, Gaussian mixture model (GMM), radial basis function (RBF), or the like). In embodiments a data is derived from a self-organizing process that reveals a multivariable continuous function that explains the data to be predicted from the available measurements. The embodiments provide a model that provides a perfect explanation (e.g., a specificity of one (1) and a sensitivity of one (1)). If the model generated is not perfect, there is insufficient data, such as from a lack of data from sensors of a specified type, placement, sensitivity, or the like or a lack of orthogonalized features extracted from those sensors. The lack of orthogonalized features can be from over fit bias from data multicollinearity. This means that the model without a perfect explanation is an approximation and not an explanation. Only a perfect explanation suffices for a testable hypothesis that explains all observations.

After the model is generated, the model can be sampled. The samples can be tabulated to provide insight into the nature and complexity of a decision boundary. Interpolation can be performed to provide more data between data samples. Extrapolation can be performed to extend the model beyond the minimum and maximum data values (e.g., by as many sigma as deemed of interest). The result is a decision boundary of model validity. Regions outside the boundaries are where the model is not valid due to over flow or under flow, sometimes called overfit in ML or statistics. The regions corresponding to the overfit correspond to operational regimes outside the relevancy of the model. Another model can be generated to explain the operation in the overfit region or more data can be gained that corresponds to operation in the overfit region and the model can be re-generated with the added knowledge to perfectly explain the behavior in the overfit region. This knowledge of where a model applies and does not apply (identifying model boundaries) is a new revolution in predictive maintenance and responsibility.

More experiments can be performed to sample at or near the boundaries of the model, such as to gain more direct observations and enable re-deriving the model and explanation. The regions where blow up occurs are more problematic because they are regimes where the hypothesis that has explained all data thus far cannot explain the behavior of the device. If these regimes are operationally accessible, it is prudent to get measurements from this regime, such as to attempt a new explanation. If not possible, a different explanation can be derived to explain (perfectly explain) the different dynamics in different operating regimes. This multiple model approach can enable prediction of target variables and states. After the operational regime is fully populated with adequate sensors and sufficient explanatory model confidence is gained in accurate reliability prediction of early failure and requirement for maintenance.

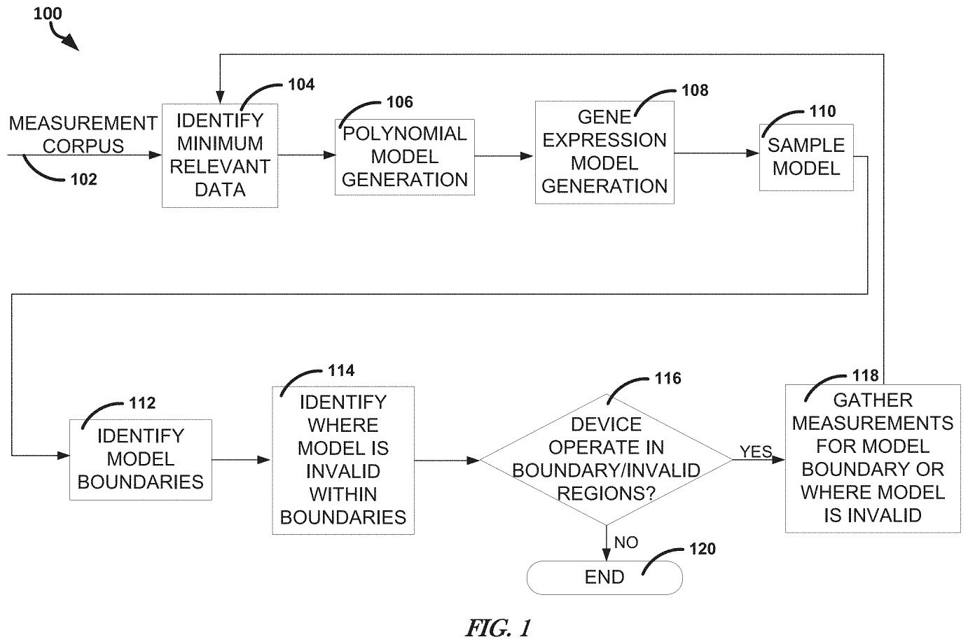

FIG. 1 illustrates, by way of example, a diagram of an embodiment of a method 100 for device analysis and verification. The method 100 is an alternative to DOE. Using the method 100, a product or prototype is not needed. The method 100 can be used to inform design of a theoretical, currently non-existing product or can be used to inform design improvements to an already existing product.

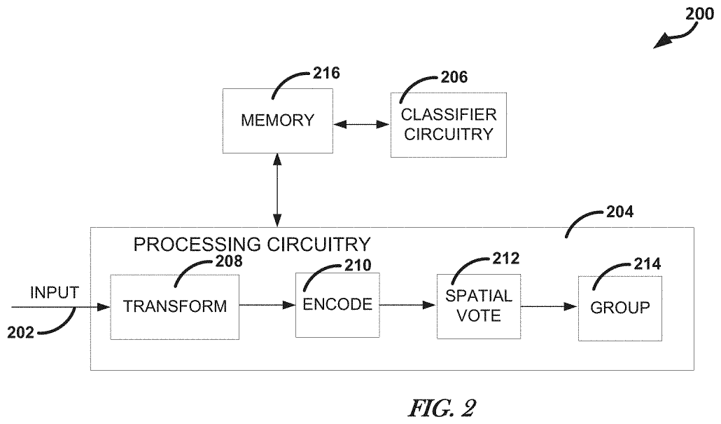

The method 100 as illustrated includes identifying minimum relevant data of a measurement corpus 102, at operation 104. The measurement corpus 102 can be from systems or devices that include one or more components, characteristics, features, or the like, that are same or similar to a device or system to be designed or analyzed using the method 100. The operation 104 can include using spatial voting (SV) to determine features of measurements in the measurement corpus 102. The determined features can be mapped to a grid of cells. The data in each cell of the grid of cells can be represented by a single data point that mapped to the cell. The single data point can be a data point closest to a center of the cell, the first data point that mapped to the cell, a synthetic data point that is some combination or statistic of the data points that map to the cell (e.g., a mean, median, mode, or the like). This operation reduces the amount of data used to generate the model. More details regarding SV and synthetic data are provided regarding FIGS. 2-9.

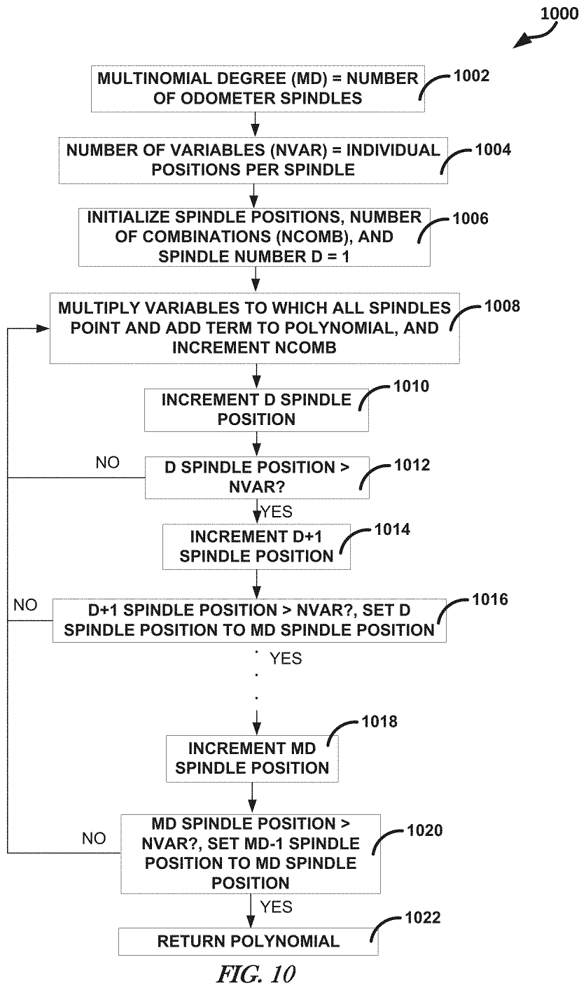

The operation 106 can include generating a polynomial model of the minimum relevant data identified at operation 104. In some embodiments, the operation 106 is optional and can be skipped. The operation 106 can include determining a full polynomial that explains the minimum relevant data with a specificity of 1 and a sensitivity of 1. More details regarding the operation 106 are provided regarding FIGS. 10-13.

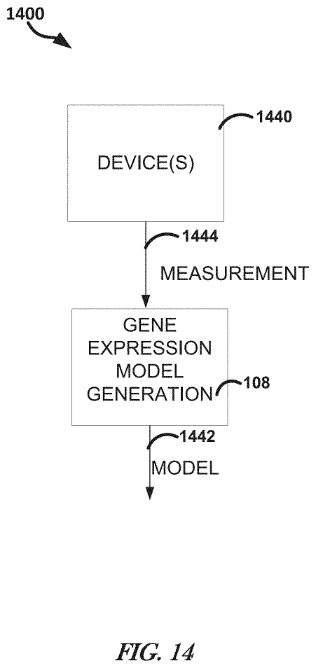

The operation 108 can include determining another model for the minimum relevant data identified at operation 104. The model generated using the operation 108 can be much more compact than the model generated using the operation 106. The model generated using the operation 108 can thus be sampled faster (in terms of compute cycles), less memory-intensive (consume less memory space), and be just as accurate in explaining the minimum relevant data identified at operation 104 as the model generated at operation 106. The model from the operation 106 can provide a sort of ground truth for the model generated at operation 108. More details regarding the operation 108 are provided regarding FIGS. 14-16.

At operation 110, the model (either from the operation 106 or the operation 108) can be sampled. The operation 110 can include providing one or more inputs to the model and recording the output. The sampling can be random, systematic, or the like.

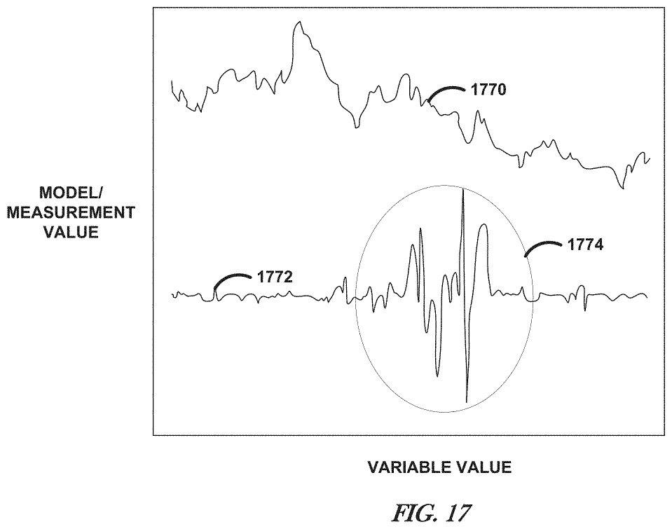

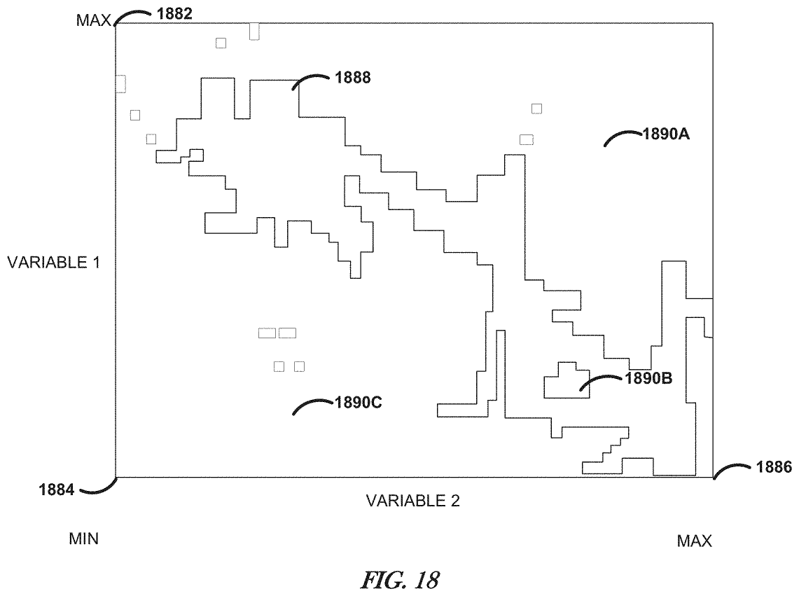

At operation 112, model boundaries can be identified, such as based on the operation 110. The model boundaries define where the model is valid and where the model is invalid. FIGS. 17 and 18 illustrate examples of results of operations 106, 108, 110, 112. The region within the boundaries are where the model is valid and the region outside the boundaries are where the model is invalid. The boundaries are defined by the minimum and maximum values for variables used to determine the model.

Notwithstanding the identification of the model boundaries at operation 112, there may be locations within the boundaries at which the model is not valid. The invalid areas are where the model blows up (provides a non-sensical result, is non-differentiable, or the like). These areas can be identified by identifying where the generated model has higher than a specified threshold error. These areas can be identified by observing the sampled model and identifying regions where the model has sporadic behavior, such as by switching operational regimes frequently or switching to an inconsistent operations regime.

At operation 116, it can be determined if the device operates near or in the boundary regions identified at operation 112 or in or near the invalid region identified at operation 114. If either these is true, measurements can be gathered for the model boundary or where the model is invalid at operation 118. In some embodiments, the measurements gathered at operation 118 can then be added to the measurement corpus 102 and used to generate a new model (such as if the measurements are to help explain behavior at the model boundaries). In some embodiments, the measurements gathered at operation 118 can be used to generate an additional model at operation 106 or 108. The additional model can be used in addition to the previous model to provide a more complete explanation of the device or system behavior. In either case, the operation 104 can be used to identify the minimum relevant data of the measurements gathered at operation 118. If it is determined at operation 116 that the device or system does not operate in or near the identified boundaries (identified at operation 112) or in or near the identified invalid regions (identified at operation 114), the process can end at operation 120. This is because a model is provided that can be used to explain the behavior of the device or system under operating conditions.

FIG. 2 illustrates, by way of example, a diagram of an embodiment of a system 200 for SV. The system 200 can identify minimum relevant data in a corpus. The minimum relevant data can include the data deemed an “anomaly”, synthetic data, or other data or combination of data mapped to a cell. The system 200 as illustrated includes processing circuitry 204, classifier circuitry 206, and a memory 216. The processing circuitry 204 can identify an anomaly (a behavior that has not been seen by the processing circuitry 204 up to the point the behavior is seen). The classifier circuitry 206 can present the anomaly to a user for action, adjust SV grid parameters, or the like. The memory 216 can store key values, SV grid parameters, or other data input or output from the processing circuitry 204.

The processing circuitry 204 receives input 202. The input 202 can include binary data, text, signal values, image values, or other data that can be transformed to a number. The input 202 can be a measurement from the corpus 102 (see FIG. 1). The processing circuitry 204 can transform the input 202 to a number, at operation 208. The operation 208 can include encoding the input into a specified format, parsing the data into chunks (e.g., chunks of a specified size), or the like. For example, the operation 208 can include encoding text input to an American Standard Code for Information Interchange (ASCII) encoding to transform the input 202 into numbers between zero (0) and two hundred fifty-five (255). In another example, the operation 208 can include converting chunks of binary data to their numerical equivalent, such as two's complement, unsigned integer, floating number (e.g., short or long), or the like. In yet another example, the operation 208 can include performing an analog to digital conversion on analog signal data, such as by an analog to digital converter. In yet another example, the operation 208 can include combining red, green, blue (RGB) values of a color image, or the like, to generate a number. Not all input 202 needs to be transformed, thus the operation 208 is optional.

The processing circuitry 204 can receive numbers either as raw input 202 or from the operation 208 and encode the numbers into two features (discussed below) at operation 210. The operation 210 is order-sensitive, such that the same inputs received in a different order encode (likely encode) to different features.

Examples of features include RM, RS, SM, SS, TM, TS, OC1, OC2, and OCR (discussed below). These calculations are performed in the sequence shown so that they can be calculated in a single pass across the data element where a value derived by an earlier step is used in an antecedent step directly and all calculations are updated within a single loop. RM can be determined using Equation 1:

RMᵢ=(RMᵢ₋₁+Xᵢ)/2 Equation 1

In Equation 1, Xᵢ is the ith input value for i=1, 2 . . . n.

RS can be determined using Equation 2:

$${RS}_{i} = ( {RS}_{i - 1} + \sqrt{\frac{{( {X}_{i} - {RM}_{i} )}^{2}}{2}} ) / 2 \qquad Equation 2$$

SM can be determined using Equation 3:

SMᵢ=ΣXᵢ/n Equation 3

SS can be determined using Equation 4:

SSᵢ=(SSᵢ₋₁+(Xᵢ−SMᵢ)²)/(n−1) Equation

TM can be determined using Equation 5:

TMᵢ=(TMᵢ₋₁+SMᵢ₋₁)/2 Equation 5

TS can be determined using Equation 6:

$${TS}_{i} = ( {TS}_{i - 1} + \sqrt{\frac{{( {X}_{i} - {TM}_{i} )}^{2}}{2}} ) / 2 \qquad Equation 6$$

Orthogonal component 1 (OC1) can be determined using Equation 7:

OC1ᵢ=(RMᵢ+SMᵢ+TMᵢ)/3 Equation 7

Orthogonal component 2 (OC2) can be determined using Equation 8:

OC2ᵢ=(RSᵢ+SSᵢ+TSᵢ)/3 Equation 8

Orthogonal component rollup (OCR) can be determined using Equation 9:

OCRᵢ=OC1ᵢ+OC2ᵢ Equation 9

There is no “best” encoding for all use cases (Ugly Duckling Theorem limitation). Each set of encoding features used as (x, y) pairs will yield a different but valid view of the same data, with each sensitive to a different aspect of the same data. “R” features tend to group and pull together, “S” features tend to spread out, “T” features tend to congeal data into fewer groups, but sub groups tend to manifest with much more organized structure, and “OC” features tend to produce the most general spread of data. “OC” features most resemble PC1 and PC2 of traditional Principal Component Analysis (PCA) without the linear algebra for eigenvectors.

Example features are now described in more detail with suggested application:

R-type feature—Associates data into closer, less spread groups, guaranteed to be bounded in SV data space if the encoding is bounded and the SV space is similarly bounded (e.g., if ASCII encoding is used and the x and y extent are bounded from [000]-[255]). R-type features are recommended when the dynamic variability in data is unknown (typically initial analysis). This can be refined in subsequent analysis. R-type features will tend to group data more than other features.

S-type feature—Tends to spread the data out more. How the encoded data spreads can be important, so things that stay together after spreading are more likely to really be similar. S-type features produce a potentially unbounded space. S-type features tend to spread data along one spatial grid axis more than another. Note, if the occupied cells in the SV spatial grid fall along a 45-degree line, then the 2 chosen stat types are highly correlated and are describing the same aspects of the data. When this occurs, it is generally suggested that one of the compressive encoding features be changed to a different one.

T-type feature—These compressive encoding features are sensitive to all changes and are used to calculate running mean and running sigma exceedances. T-type features can provide improved group spreading over other features types. T-type features tend to spread data along both axes.

OC-type feature—Orthogonal Components, which are simple fast approximations to PCA (Principal Component Analysis). The OC1 component is the average of RM, SM, and TM, OC2 is the average of RS, SS, and TS, and OCR is the sum of OC1 and OC2.

Note that while two variants of each type of feature are provided (e.g., RS and RM are each a variant of an R-type feature) cross-variants can provide a useful analysis of data items. For example, if an RS or RM is used as feature 1, any of the S-type features, T-type features, or OC-type features can also be used as feature 2. Further, two of the same features can be used on different data. For example, TS on a subset of columns of data from a row in a comma separated values (CSV) data file can form a feature 1, while TS on the same row of data but using a different subset of columns can form a feature 2.

In some embodiments, one or more features can be determined based on length of a corresponding data item. The length-based features are sometimes called LRM, LRS, LSM, LSS, etc.

The features of Equations 1-9 are order-dependent. The features can be plotted against each other on a grid of cells, at operation 212. The processing circuitry 204 can initialize an SV grid to which the encoded inputs are mapped, such as at operation 212.

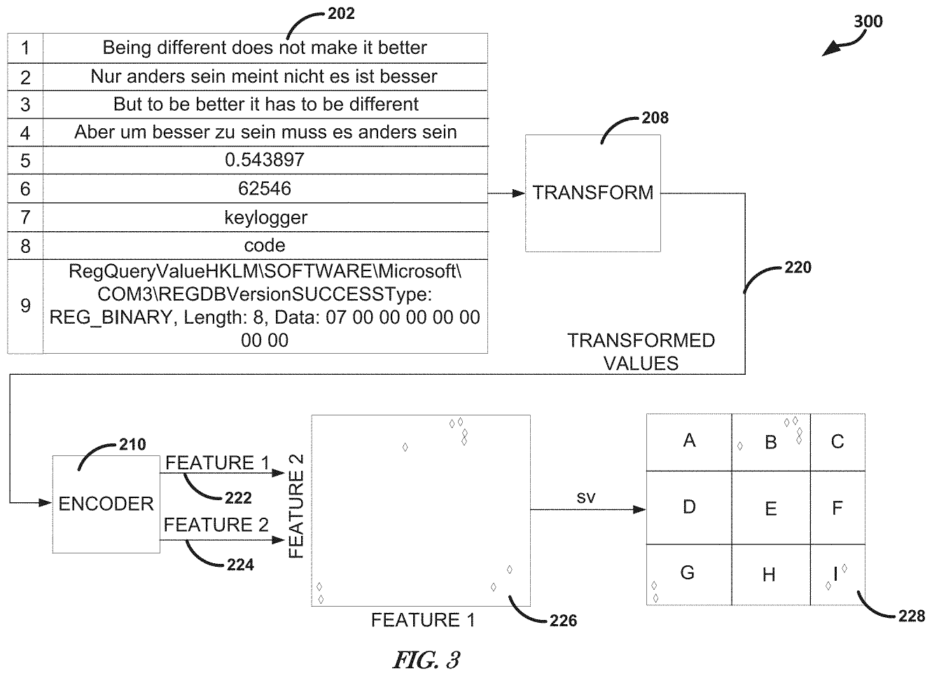

Plotted values can be associated or correlated, such as at operation 214. The operation 214 can include forming groups of mapped inputs and determining an extent thereof. More details regarding the operations 208-214 are provided in FIGS. 3-5.

The classifier circuitry 206 can provide a user with a report indicating behavior that is anomalous. An input mapped to a cell that was not previously populated is considered anomalous. If an input is mapped to a cell that already has an input mapped thereto by the features, the input can be considered recognized or known. Since some applications can be memory limited, an entity can opt to have few cells in an SV grid. For these cases, it can be beneficial to determine an extent that an encoded value is situated away from a center of a cell. If the encoded value is a specified distance away from the center or a center point (e.g., as defined by a standard deviation, variance, confidence ellipse, or the like), the corresponding data item can be considered anomalous. Such embodiments allow for anomaly detection in more memory-limited devices.

The classifier circuitry 206, in some embodiments, can indicate in the report that an input known to be malicious was received. The report can include the input, the group (if applicable) to which the cell is a member, a number of consecutive inputs, a last non-anomalous data item, a subsequent non-anomalous data-item, such as for behavioral analysis or training, or the like. The classifier circuitry 206 can indicate, in the report, different types of anomalies. For example, a type 1 anomaly can indicate a new behavior that falls within an area of regard (AOR). A type 2 anomaly can indicate a new behavior that falls outside of an area of regard. An area of regard can be determined based on one or more prior anomaly detection epochs. In a given epoch, there can be one or more areas of regard. An anomaly detection epoch is a user-defined interval of analyzing a number of inputs, a time range, or the like. The epoch can be defined in the memory 816 and monitored by the processing circuitry 204.

In some embodiments, an event for the report can include a single anomalous behavior. In some embodiments, an event for the report can be reported in response to a specified threshold number of type 2 anomalies.

The classifier circuitry 206 can adjust SV grid parameters. An initial size of an SV grid cell can be determined. In some embodiments, the initial size of the SV grid cell can include dividing the space between (0, 0) and the encoded (x, y) of the first input data item into an N×N SV grid, where N is the initial number of cells on a side of the SV grid (for example, a 16×16 SV grid would break up the distance in x and in y to the first data point from the origin into 16 equal divisions).

As new input data items are introduced and encoded, whenever one fall outside the extent of the SV grid, the N×N SV grid can be increased in size to (N+1) x (N+1) until either the new input data item is included on the resized SV grid, or N becomes equal to the maximum allowed number of SV grid cells on a side of the SV grid. After N becomes a defined maximum SV grid size (for example 64×64), and a new input data item falls off of the current SV grid, the size of each SV grid cell size can be increased so that the SV grid encompasses the new data point.

As either the number of SV grid cells on a side or the overall extent of the SV grid in x and y are increased to encompass new input data items, the SV grid column (Equation 14), SV grid row (Equation 15), and key index value (Equation 16) can be changed to map the populated SV grid cells from the previous SV grid to the newly size one. To accomplish this, the center (x, y) value of each populated SV grid cell can be calculated using the minimum and maximum x and y values and the number of SV grid cells in the previous SV grid, and then mapping the centers and their associated SV grid counts onto the new SV grid using Equations 14, 15, and 16. This is done using the following equations:

Row=int(Key Value/(number of cells on side)) Equation 10

Col=Key Value−int(Row*(number of cells on side)) Equation 11

Center 1=x min+Col*(x range)/(num. col−1) Equation 12

Center 2=y min+Row*(y range)/(num. row−1) Equation 13

The values for Center 1 and Center 2 can then be used in Equations 14, 15, and 16 (below) as Feature 1 and Feature 2 to calculate the new Key Value for each populated cell on the new SV grid.

FIG. 3 illustrates, by way of example, a diagram of an embodiment of a method 300 for identifying an anomalous behavior. The method 300 as illustrated includes receiving the input 202. The input 202 in FIG. 3 includes nine text strings labelled “1”-“9”. Each of the text strings “1”-“9” of the input 202 is respectively transformed to transformed values 220 at operation 208. An example transformation is ASCII encoding which transforms text to numerical values. The transformed values 220 can be used to perform the operation 210. The operation 210 can include determining two features 222, 224 of the input 202 and plotting them against each other to form a feature graph 226. The features 222, 224 can include, for example, RM, RS, SM, SS, TM, and TS, in some embodiments.

Consider the input data item “1”. Each character of the input data item “1” can be transformed to an ASCII value. The features can be determined based on the ASCII encoding of the entire string. That is, Xᵢ, is the ASCII value of each character and the features are determined over all ASCII encodings of the characters of the input data item “1”. As an example, the resultant RM can be feature 1 222 and the resultant RS can be feature 2 224, or vice versa. This is merely an example and any order-dependent feature can be chosen for feature 1 and any order-dependent feature chosen for feature 2. Each of the input data items “1”-“9” can be processed in this manner at operation 208 and 210.

The graph 226 can then be split into cells to form a grid 228. The cells of FIG. 3 are labelled “A”-“I” for illustration (Key Values are numeric labels of the SV grid cells from Equation 16). Inputs 202 mapped to a same cell can be considered similar. Inputs 202 mapped to an empty cell can be considered anomalous. In the grid 228, input data items “1”-“4” (sentences in English and German) are mapped to cell “B”, input data items 5-6 (numbers) are mapped to cell “I”, and input data items “7-8” (words) are mapped to cell “G”. Input data item 9, which is a combination of words, numbers, and other characters, maps to cell “B” indicating that input data item “9” is more like a sentence than a word or number. If a subsequent input data item 202 were to be received and mapped to cell “A”, “C”, “D”, “E”, “F”, or “H” it can be deemed anomalous, as it is a behavior that has not been received before and is sufficiently different from other behaviors that have been seen previously.

As can be seen, whether an input is considered an anomaly is dependent on a size of a cell. The size of the cell can be chosen or configured according to an operational constraint, such as a size of a memory, compute bandwidth, or the like. The size of a cell can be chosen or configured according to a desired level of security. For example, a higher level of security can include more cells, but require more memory and compute bandwidth to operate, while a lower level of security can include fewer cells but require less memory and bandwidth to operate.

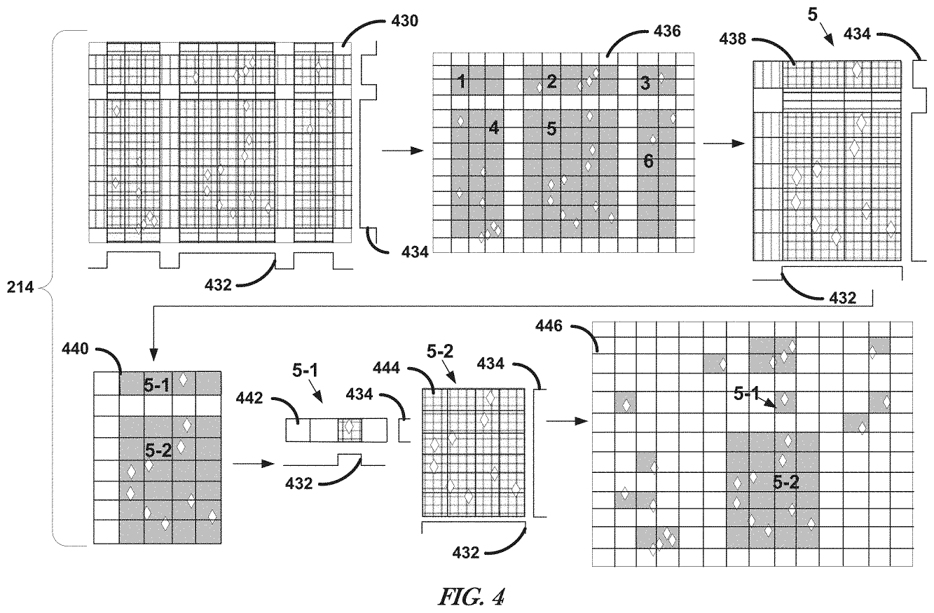

FIG. 4 illustrates, by way of example, a diagram of an embodiment of the operation 214. Encoded inputs ((x, y) points) are represented by diamonds. The operation 214 (sometimes called shadowing for group extraction) can include an iterative process that identifies cells that are populated and aggregates and separates those cells into groups. The iterative process can include:
1) Identifying cells of columns with at least one populated cell at operation 432 (indicated by horizontal hashing in graph 430)
2) Identifying cells of rows with at least one populated cell at operation 434 (indicated by vertical hashing in graph 430)
3) For each cell identified at both (1) and (2) (indicated by cross-hashing in the cell), (a) aggregate with all contiguous cells identified at both (1) and (2), (b) assign aggregated cells to a group, and (c) label the group with a key
4) Repeat (1)-(3) for each group/sub-group until no change.

A graph 436 illustrates the result of a first iteration of performing the operations (1)-(3). After the first iteration, six groups “1”-“6” in FIG. 4 are formed. Next each of the groups “1”-“6” are processed by operations (1)-(3). In FIG. 4, the second iteration is illustrated for group “5”. The operations 432 and 434 can be performed on a sub-grid 438 formed by the cells of group “5”. A graph 440 illustrates the result of the second iteration of performing the operations (1)-(3). After a second iteration on group “5”, two sub-groups “5-1” and “5-2” are formed in the example of FIG. 4.

In the example of FIG. 4, a third iteration of the operations (1)-(3) is performed on the subgroups “5-1” and “5-2”. The operations 432 and 434 can be performed on sub-grids 442, 444 formed by the cells of sub-groups “5-1” and “5-2”. A graph 446 illustrates the result of the performing all iterations of the operations (1)-(3) and the groups formed therefrom.

In some embodiments, the number of cells can be adaptive, such as to be adjusted during runtime as previously discussed. Related to this adaptive cell size is determining the location of an encoded input in the grid and a corresponding key value associated with the encoded input. An example of determining the location in the grid includes using the following equations (for an embodiment in which feature 1 is plotted on the x-axis and feature 2 is plotted on the y-axis):

Col=int((feature 1−x min)*(num. col−1)/(x range)) Equation 14

Row=int((feature 2 y min)*(num. row−1)/(y range)) Equation 15

An encoding on the grid, sometimes called key value, can be determined using Equation 16:

Key Value=num. row*Row+Col Equation 16

The “x min”, “y min”, “x max”, and “y max” can be stored in the memory 216. Other values that can be stored in the memory 216 and relating to the grid of cells include “max grid size”, “min grid size”, or the like. These values can be used by the processing circuitry 204 to determine “x range”, “num. col.”, “y range”, or “num. row”, such as to assemble the grid of cells or determine a key value for a given encoded input (e.g., (feature 1, feature 2)).

A series of key values representing sequential inputs can be stored in the memory 216 and used by the classifier circuitry 206, such as to detect malicious (not necessarily anomalous) behavior. A malicious or other behavior of interest can be operated on by the processing circuitry 204 and the key values of the behavior can be recorded. The key values can be stored and associated with the malicious behavior. Key values subsequently generated by the processing circuitry 204 can be compared to the key values associated with the malicious behavior to detect the malicious behavior in the future.

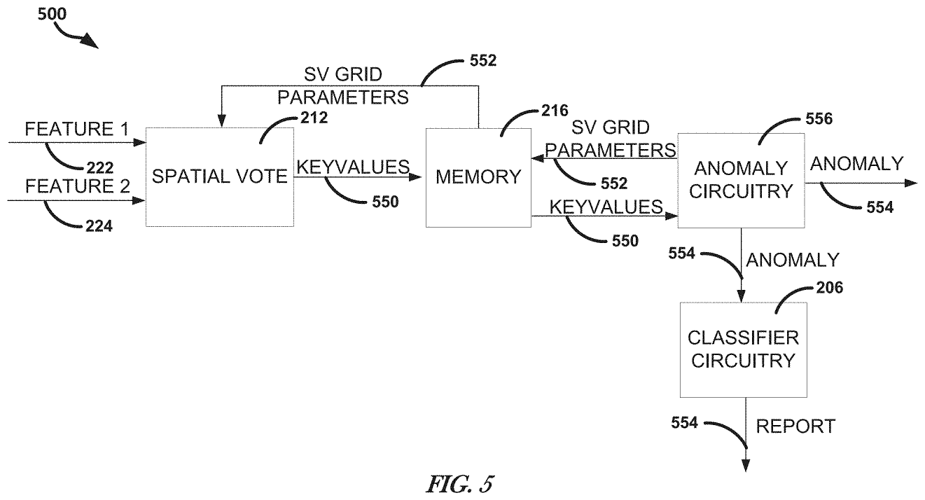

FIG. 5 illustrates, by way of example, a diagram of an embodiment of a system 500 for anomaly detection. The system 500 includes an exploded view diagram of a portion of the system 200. The system 500 as illustrated includes the operation 212 of the processing circuitry 204, the memory 216, the classifier circuitry 206, and anomaly circuitry 556. The operation 212 determines key values 550 based on SV grid parameters 552 from the memory 216 and features 222, 224 determined by the processing circuitry 204. The anomaly circuitry 556 can provide data indicating inputs mapped to a behavior never seen before (e.g., data mapped to a cell that was not populated previously).

The key values in the memory 216 can allow for F-testing, t-testing, or Z-score analysis, such as by the classifier circuitry 206. These analyses can help identify significant columns and cells. The classifier circuitry 206 can provide event and pre-event logs in a report 554, such as for further analysis. The report 554 can provide information on which column or cell corresponds to the most different behavior.

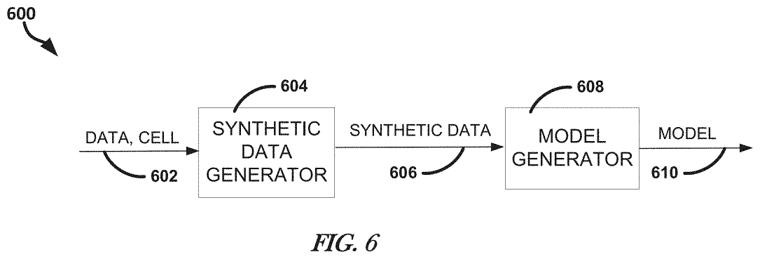

FIG. 6 illustrates, by way of example, a diagram of an embodiment of a system 600 for synthetic data generation and model generation. The system 600 as illustrated includes a synthetic data generator 604 and a model generator 608 (e.g., the polynomial model at operation 106 and/or the gene expression model at operation 108). The synthetic data generator 604 generates synthetic data 606 based on data, cell 602, such as from the system 500. The data, cell 602 can include all determined features 222, 224 of measurements from the corpus 102 and cell to which the measurements are mapped. The model generator 608 can generate a model 610 of (a mathematical equation that explains) the measurements of the measurement corpus 102.

The data, as previously discussed, can include variables that can be output from one or more processes or devices. The processes or devices can be any of a wide range of sensors, firewalls, network traffic monitors, bus sniffers, or the like. The processes or devices can provide variable data in a wide variety of formats, such as alphanumeric, character, strictly numeric, list of characters or numbers, strictly alphabet, or the like. Any non-numeric input can be converted to a numeric value as part of the SV operation (see FIGS. 2-5 for further details).

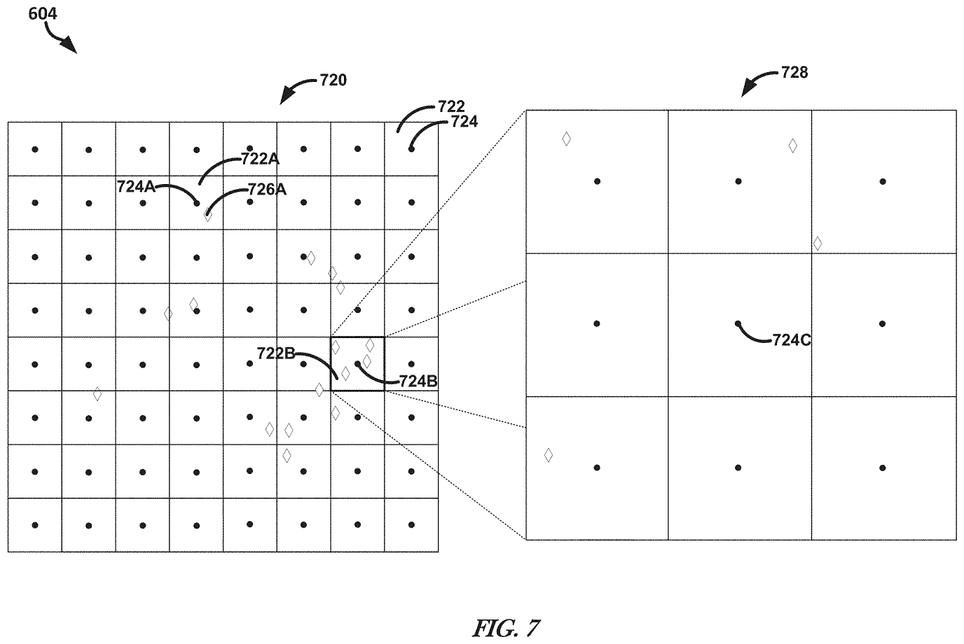

FIG. 7 illustrates, by way of example, a portion of a synthetic data generation process, such as can be performed by the SV data generator 604. The SV operation converts N-numeric values (feature vectors) to values of two features (same feature on different data or different features on same data) and maps the two features to an SV grid 720. The SV grid 720 includes cells 722 (of equal size and extent) each with a corresponding cell center 724. The cell center 724 can serve as a convenient reference point for the cell 722.

The diamonds 726 represent respective locations to which a measurement from the corpus 102 is mapped based on a determined feature. For more information regarding the types of features and other details of SV operations, please refer to FIGS. 2-5.

The synthetic data generator 604 generates the synthetic data 606 based on features of measurements. The synthetic data 606 can include, for each cell, an average of all features of data mapped thereto. For a cell that includes only a single measurement mapped thereto, the average is trivial and is just the value of the features (e.g., variables) of the I/O example represented by the diamond 726. For example, the cell 722A has only a single measurement mapped thereto, so the synthetic data 606 for the cell 722A is the value of the variables of that measurement. The synthetic data 606 can then be associated with the center 724A of the cell.

The cell 722B includes multiple I/O examples mapped thereto. In such a case, the individual variables are averaged per variable, to determine a single value for each variable to be associated with the center of the cell 722B. Assume the I/O examples that map to the cell 722B have the following values (along with an optional class.

| I/O Example | variable 1 | variable 2 | variable 3 | variable 4 | variable 5 | variable 6 |
|---|---|---|---|---|---|---|
| 1 | value 1 | value 5 | value 9 | value 13 | value 17 | value 21 |
| 7 | value 2 | value 6 | value 10 | value 14 | value 18 | value 22 |
| 11 | value 3 | value 7 | value 11 | value 15 | value 19 | value 23 |
| 16 | value 4 | value 8 | value 12 | value 16 | value 20 | value 24 |

Note that six variables per measurement is merely an example, and more or fewer variables (e.g., features of a feature vector) can be used. The synthetic data value associated with the center 724B can be the average of each value of the variable so the value of the synthetic data 606 for the cell 722B in this example can be:

Synthetic Data=(Avg(value1,value2,value3,value4),Avg(value5,value6,value7,value8),Avg(value9,value10,value11,value12),Avg(value13,value14,value15,value16),Avg(value17,value18,value19,value20),Avg(value21,value22,value23,value24))

Avg can include the mean, expectation, median, mode, fusion of values, ensembling, lossy compression, or other average.

Like measurements can be voted to a same or nearby cell. This is, at least in part because the SV operation has the ability to vote similar measurements to same or nearby cells. The synthetic data 606 generated at this point can be used for generating the model 610, such as by the model generator 808.

However, in some embodiments, the data, cell 602 can be important or the synthetic data 606 can be used in a specific process that requires more data analysis. In such embodiments, the mapped data (represented by the diamonds 726) can be further processed.

Consider again, the cell 722B and the four mapped data points. Also, assume that the respective classes associated with two or more of the four mapped data points are different. The cell 722B can be further divided further into a sub-grid 728. The number of cells in a row and column of the sub-grid 728 can be rounded up to the nearest odd integer, and determined by the following equation:

maximum(3,sqrt(number of points mapped to cell))

The centers 724B and 724C can correspond to the same point, while the remaining centers of the sub-grid 728 correspond to different points. The variables of the data, cell 602 mapped to a same cell 722 can be averaged (in the same manner as discussed previously) to generate the synthetic data 606 for that cell.

In the example of FIG. 7, all the cells of the grid 728 include only a single point mapped thereto, thus there is no class conflict and the process can end. However, further sub-dividing of the grid can be required in some examples to remove class conflicts.

The synthetic data 606 from the grid 720 is sometimes called L2 synthetic data and the synthetic data 606 from the grid 728 is sometimes called L1 synthetic data. In examples in which data mapped to a cell in the grid 728 includes disparate classes, the cell can be further subdivided until the data in each cell no longer includes a conflicting class designation. In such examples, the synthetic data from the final subdivided grid is considered L1 synthetic data and the synthetic data from the immediately prior grid is considered L2 synthetic data.

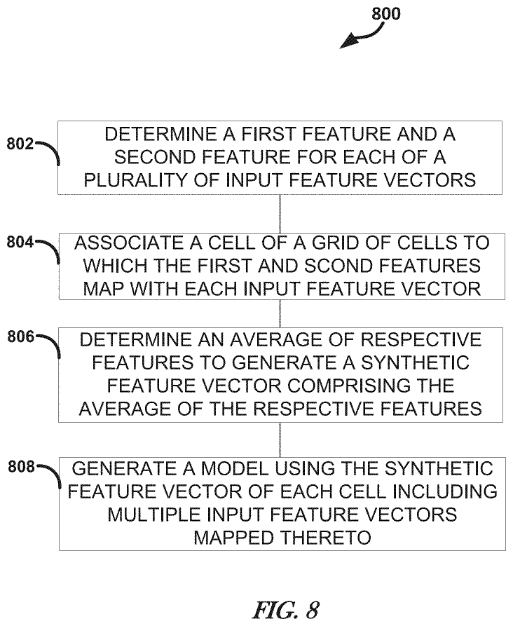

FIG. 8 illustrates, by way of example, a diagram of an embodiment of a method 800 for generating and using synthetic data (e.g., for model generation). The method 800 as illustrated includes determining a first feature and a second feature for each of a plurality of input feature vectors, at operation 802; associating a cell of the grid of cells to which the first and second features map with each input feature vector, at operation 804; determining (e.g., for each cell that includes multiple input feature vectors associated therewith and based on features of the input feature vectors mapped thereto) an average of respective features to generate a synthetic feature vector comprising the average of the respective features, at operation 806; and generating a measurement model using the synthetic feature vector of each cell including multiple input feature vectors mapped thereto, at operation 808. The operation 802 can include, given the same numbers in a different order, producing a different value for the respective feature of the first and second features. The method 800 can further include, wherein each input feature vector includes an associated class and the processing circuitry is further configured to generate a sub-grid of sub-cells for each cell of the grid of cells that includes input feature vectors with different associated classes associated therewith.

The method 800 can further include, wherein the sub-grid of sub-cells includes a number of cells greater than, or equal to, a number of input feature vectors mapped thereto. The method 800 can further include, wherein the number of rows and columns of sub-cells is odd and the sub-grid includes a number of rows and columns equal to a maximum of (a) three and (b) a square root of the number of input feature vectors mapped thereto. The method 800 can further include, wherein the sub-grid includes a same center as the cell for which the sub-grid is generated. The method 800 can further include, wherein the synthetic feature vector is determined based on only feature vectors associated with a same class.

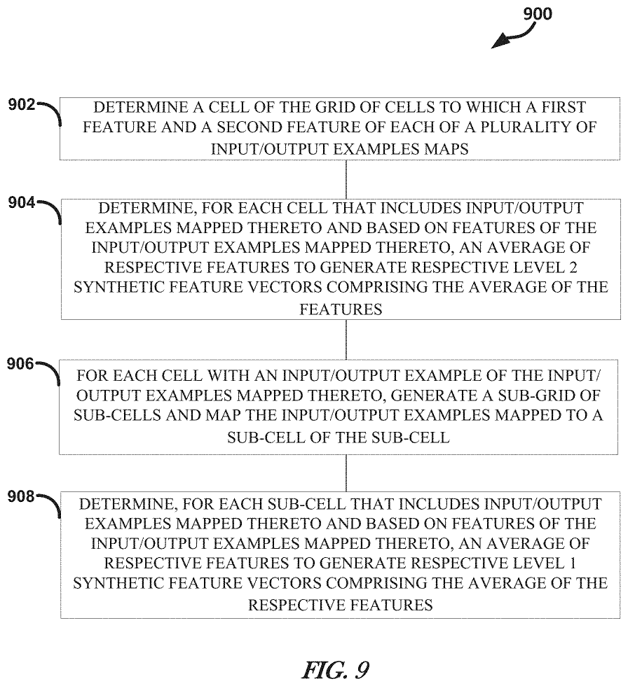

FIG. 9 illustrates, by way of example, a diagram of an embodiment of a method 900 for generating synthetic data. The method 900 as illustrated includes determining a cell of a grid of cells to which a first feature and a second feature of each of a plurality of measurements maps, at operation 902; determining, for each cell that include one or more measurements mapped thereto and based on features of the measurements mapped thereto, an average of respective features to generate respective level 2 synthetic feature vectors comprising the average of the features, at operation 904; for each cell with a measurement of the measurements mapped thereto, generating a sub-grid of sub-cells and map the measurements mapped to a sub-cell of the sub-cell, at operation 906; and determining, for each sub-cell that includes measurements mapped thereto and based on features of the measurements mapped thereto, an average of respective features to generate respective level 1 synthetic feature vectors comprising the average of the respective features, at operation 908.

FIG. 10 illustrates, by way of example, a diagram of an embodiment of a flow chart for an odometer method 1000 for generating a complete polynomial of a specified order. In some instantiations, the odometer method 1000 creates n-variable complete polynomials of a specified order. The method 1000 is implemented at one or more computing machines, for example, the computing machine 1900.

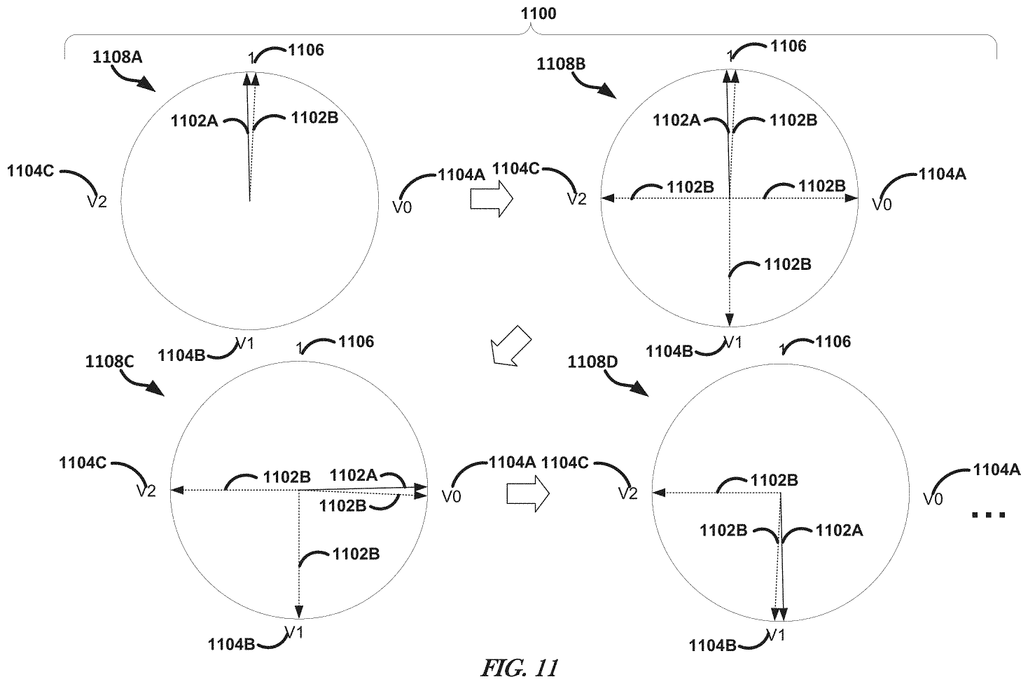

At operation 1002, the computing machine 1900 receives a multinomial degree (MD), which may be represented as a number of odometer spindles 1102 (see FIG. 11). Spindles refer to spindles of an odometer in a car with spindles for hundred-thousands, ten-thousands, thousands, hundreds, tens, and singles of miles. The MD can be, for example, two (2), three (3), or a greater integer.

At operation 1004, the computing machine 1900 receives a number of variables (NVAR). The NVAR may be represented as a number of individual positions per spindle. The NVAR can be an integer greater than one (1). A number of variables 1104 (see FIG. 11) that line an odometer 1108 (see FIG. 11) can be equal to NVAR.

At operation 1006, the computing machine 1900 can generate the odometer 1108 (see FIG. 11). Generating the odometer 1108 can include initializing the spindle 1102 positions (the variables 1104 to which the respective spindle 1102 points) can be initialized. The operation 1006 can include setting the number of combinations (Ncomb) to one. Ncomb counts the number of terms in a polynomial generated using the odometer method 1000. In the created odometer, each spindle represents a degree of the multinomial, and each individual position on each spindle corresponds to a variable.

At operation 1008, all variables to which the spindles 1102 point are multiplied with each other and a resulting term is added to the polynomial. At operation 1010, the position of the most minor spindle is incremented. The most minor spindle is the one that moves the most. Consider a clock with a second hand, minute hand, and hour hand. The most minor spindle would be the second hand and the most major spindle would be the hour hand.

At operation 1012, it is determined whether the spindle position of the most minor spindle is greater than NVAR. If the spindle position is less than NVAR, the method 1000 continues at operation 1008. If the most minor spindle position is greater than NVAR, the spindle position of the next most minor spindle (the D+1 spindle in the example of FIG. 1) is incremented at operation 1014.

At operation 1016, the most minor spindle is set to the position of the most major spindle (the MD spindle) and it is determined whether the next most minor spindle position is greater than NVAR. If the next most minor spindle position is less than (or equal to) NVAR the method 1000 continues at operation 1008. If the next most minor spindle position is greater than NVAR, the method 1000 continues with operations similar to operations 1014 and 1016 with spindles of increasing strength until all but the position of the most major spindle have been incremented NVAR times. At this point, the most major spindle is incremented in position at operation 1018.

At operation 1020, it is determined whether the most major spindle position is greater than NVAR. If the most major spindle position is less than (or equal to) NVAR, the method 1000 continues at operation 1008. If the most major spindle position is greater than NVAR, the method 1000 is complete and the generated polynomial is provided at operation 122.

FIG. 11 illustrates, by way of example, a diagram of an embodiment of the operations of the method 1000. FIG. 11 is intended to help explain the odometer technique described regarding FIG. 10. The diagram 1100 includes two spindles 1102A, 1102B and three variables 1104A, 1104B, 1104C on an odometer 1108. Other numbers of spindles 1102 and variables 1104 are possible. Two spindles and three variables are merely convenient for explanatory purposes.

The odometer 1108A is in a position after initialization (e.g., operations 1002, 1004, 1006). The odometer 1108B illustrates operations 1008, 1010, 1012. A function after the odometer 1108B in this example includes 1+V0+V1+V2.

The odometer 1108C illustrates operations 1014, 1016 and subsequent operations 1008, 1010, 1012. The spindle 1102A is incremented and the spindle 1102B is looped across the remaining variables (or identity) to which the spindle 1102A has not yet pointed. After these operations, the function in this example includes 1+V0+V1+V2+V0V0+V0V1+V0V2.

The odometer 1108D illustrates subsequent operations 1014, 1016 and subsequent operations 1008, 1010, 1012. The spindle 1102A is incremented and the spindle 1102B is looped across the remaining variables (or identity) to which the spindle 1102A has not yet pointed. After the third instance of the operations 1014, 1016 and subsequent operations 1008, 1010, 1012, the polynomial in this example includes 1+V0+V1+V2+V0V0+V0V1+V0V2+V1V+V1V2. The function generated can be referred to as an object of a layer. In this example, this function can be layer 1, object 1 (“L1O1”). Multiple objects can be generated for each layer.

The method 1000 continues until only one additional term is added to the function. The function after the odometer technique illustrated in FIGS. 10 and 11 completes is 1+V0+V1+V2+V0V0+V0V1+V0V2+V1V1+V1V2+V2V2. This is a full, second order, multivariate polynomial on the variables V0, V1, and V2.

Note that the method 1100 is only for a second order polynomial. A third order polynomial would use the operations 1018, 1020.

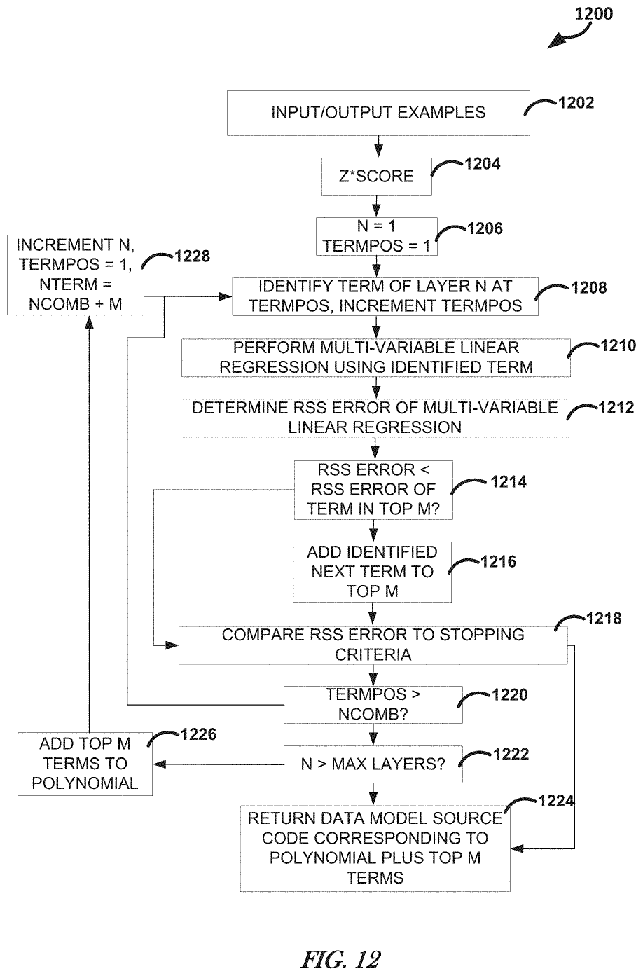

FIG. 12 is a flow chart for a method 1200 of data modeling, in accordance with some embodiments. The method 1200 is implemented at one or more computing machines, for example, the computing machine 1900.

At operation 1202, the computing machine receives, as input, a plurality of data examples (e.g. input/output (I/O) pairs).

At operation 1204, the computing machine computes a modified Z-score (z*-score) for the data examples (or a portion of the data examples). The z*-score is computed as (value−mean)/average deviation (versus standard deviation that is used to compute the standard Z-score). The value is the value of the data example. The mean is the mean of the data example values. The average deviation is calculated according to:

$$Average Deviation = {\sum }_{i = 1}^{K} \vert {x}_{i} - μ \vert / K$$

In the above equation, there are K data examples xᵢ for i=1 to K. The value μ represents the mean of the K data examples xᵢ.

At operation 1206, the computing machine sets a layer number (N) to one. At operation 1208, the computing machine proceeds to the N^{th} layer. At operation 1210, the computing machine calculates a next variable or metavariable from the data examples in a layer corresponding to the layer number. The variable combination can include one or more variables or metavariables from the function generated by the method 1100. A variable or metavariable in the function is any entry between plus signs. For the example of the function generated and described regarding FIG. 12, the variables are V0, V1, and V2, and metavariables (combinations of variables) are V0V0, V0V1, V0V2, V1V1, V1V2, and V2V2. Any of the variables and metavariables can be used up to the entire layer object.

At operation 1212, the computing machine computes a multivariable linear regression for the currently selected variable.

At operation 1214, the computing machine determines whether a residual sum of squares (RSS) error for the multivariable linear regression is less than that for at least one of a best M variables (or metavariables) to carry to the next layer. M is a predetermined positive integer, such as three (3) or another positive integer. If the RSS error is less than that for at least one of the best M variable combinations, the method 1200 continues to operation 1216. Otherwise, the method 1200 skips operation 1216 and continues to operation 1218.

At operation 1216, upon determining that the RSS error is less than that for at least one of the best M variable combinations, the computing machine adds the currently selected variable combination to the best M variable combinations (possibly replacing the “worst” of the best M variable combinations, i.e., the one having the largest RSS error).

At operation 1218, the computing machine tests the RSS error against stopping criteria. Any predetermined stopping criteria may be used. The stopping criteria may be the RSS error being less than a standard deviation of the output variable in the data examples. Alternatively, the stopping criteria may be the RSS error being less than a standard deviation of the output variable in the data examples divided by the number of samples for that output variable. Alternatively, the stopping criteria may be one or more (e.g., all) of the best M variable combinations being a function of previous layer outputs. If the test is passed, the method 1200 continues to operation 1224. If the test is failed, the method 1200 continues to operation 1220.

At operation 1220, upon determining that that the test is failed, the computing machine determines whether each and every one of the variable combinations has been used. If so, the method 1200 continues to operation 1222. If not, the method 1200 returns to operation 1210.

At operation 1222, upon determining that each and every one of the variable combinations has been used, the computing machine determines whether N is greater than or equal to the total number of layers. If so, the method 1200 continues to operation 1224. If not, the method 1200 continues to operation 1226.

At operation 1224, upon determining that N is greater than or equal to the total number of layers, the computing machine outputs the model source code. After operation 1224, the method 1200 ends.

At operation 1226, upon determining that N is less than the total number of layers, the computing machine provides the best M variables as input to the next layer.

At operation 1228, the computing machine increments N by one to allow for processing of the next layer. After operation 1228, the method 1200 returns to operation 1208.

In some cases, it is desirable to have a fully differentiable equation that represents the data. Such differentiable equations are useful for modeling dynamical systems such as those that are based on coupled measurement sets or those which change as a function of one or more of the input variables.

The Turlington function is defined in Equation 17, where d is a fitting parameter, for example, d=0.001, and N is the number of data points:

$$Turlington ( x ) = {y}_{1} + \frac{{y}_{2} - {y}_{1}}{{x}_{2} - {x}_{1}} * ( x - {x}_{1} ) + {\sum }_{j = 2}^{N - 1} d ( \frac{{y}_{j + 1} - {y}_{j}}{{x}_{j + 1} - {x}_{j}} - \frac{{y}_{j} - {y}_{j - 1}}{{x}_{j} - {x}_{j - 1}} ) {log}_{10} ( 1 + {10}^{\frac{x - {x}_{j}}{d}} ) \qquad Equation 17$$

Equation 18 defines the first derivative of the Turlington function, which is referred to as the first order Handley differential operator and is given by:

$$dHandley / dx = \frac{{y}_{2} - {y}_{1}}{{x}_{2} - {x}_{1}} + {\sum }_{j = 2}^{N - 1} ( \frac{{y}_{j + 1} - {y}_{j}}{{x}_{j + 1} - {x}_{j}} - \frac{{y}_{j} - {y}_{j - 1}}{{x}_{j} - {x}_{j - 1}} ) ( {10}^{\frac{x - {x}_{j}}{d}} / ( 1 + {10}^{\frac{x - {x}_{j}}{d}} ) ) \qquad Equation 18$$

Equation 19 defines the n^{th} order Handley differential operator, where n is a positive integer and is given by:

$${d}^{n} Handley / {dx}^{n} = B ( n ) + {\sum }_{j = 2}^{N - 1} {\sum }_{i = 1}^{n} \frac{{( - 1 )}^{i + 1}}{{d}^{n - 1}} ( \frac{{y}_{j + 1} - {y}_{j}}{{x}_{j + 1} - {x}_{j}} - \frac{{y}_{j} - {y}_{j - 1}}{{x}_{j} - {x}_{j - 1}} ) ( {10}^{\frac{x - {x}_{j}}{d}} / ( 1 + {10}^{\frac{x - {x}_{j}}{d}} ) ) {ln ( 10 )}^{n - 1} {Ψ}_{n , i} \qquad Equation 19$$

In Equation 19, the following apply:

$$B ( 1 ) = \frac{{y}_{2} - {y}_{1}}{{x}_{2} - {x}_{1}} , B ( n ) = 0 if n > 1 {Ψ}_{n , i} = {{\sum }_{j = i - 1}^{i}}_{{j \neq 0}_{j \neq n}} j {Ψ}_{n , i}$$

So, if one constructs the Handley differential operator of the data using the 2^{nd} derivative form (n=2), one can automatically obtain the analytical integral of the data by setting n=1, or the analytical j^{th} order derivative of the data by setting n=j+2.

To pre-initialize, one assumes the first two points occur at x=−1 and x=0 with y values of 0 respectively, and pre-calculate the initial Handley differential operator term and hardwire it as a starting term enabling the first live data point to generate the first new derivative term shown in Equation 19.

For some embedded applications, the natural log (In) term can be replaced with its Taylor series expansion.

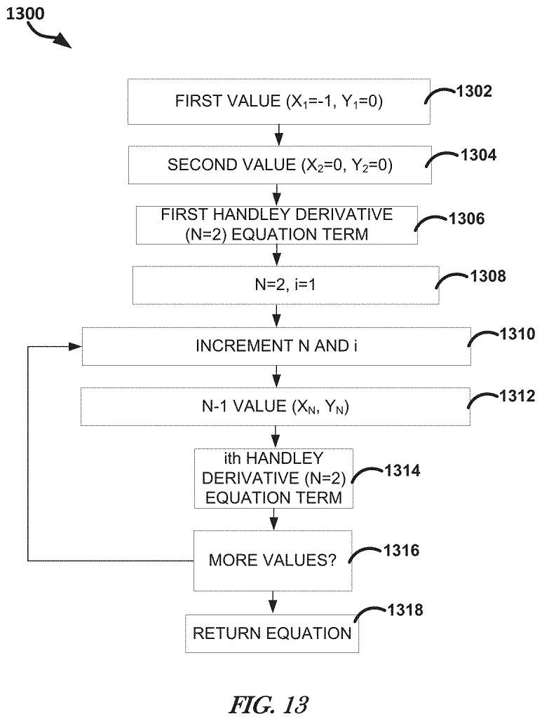

FIG. 13 illustrates a flow chart of a method 1300 for generating the Handley differential operator, such as can be used for behavior monitoring. The method 1300 can be implemented at one or more computing machines, for example, the computing machine 1900.

At operation 1302, upon receiving a set of measurements associated with actual device behavior, the computing machine sets the first value (x₁=−1, y₁=0). At operation 1304, the computing machine sets the second value (x₂=0, y₂=0).

At operation 1306, the computing machine computes the first Handley differential operator (n=2) equation term. At operation 1308, the computing machine sets N=2 and i=1.

At operation 1310, the computing machine increases N by 1 and increases i by 1. At operation 1312, the computing machine computes the N−1 value (x_{N}, y_{N}).

At operation 1314, the computing machine computes, based on the computed Handley differential operator equation terms and the received set of measurements, the i^{th} Handley derivative (n=2) equation term. At operation 1316, the computing machine determines if more values are to be computed. If more values are to be computed, the method 1300 returns to operation 1310. If no more values are to be computed, the method 1300 continues to operation 1318.

At operation 1318, upon determining that no more measurements are available, the computing machine outputs the final equation form, which is an equation based on the computed values. After operation 1318, the method 1300 ends.

FIG. 14 illustrates, by way of example, a diagram of an embodiment of a system 1400 for gene expression programming (GEP) model generation. The system 1400 as illustrated includes at least one device 1440, and the operation 108. Each device 1440 can include circuitry, software, or a combination thereof, that produces an output, called a measurement 1444. The measurement 1444 can be part of the measurement corpus 102. The measurement 1444 can include a voltage level, a current level, a power level, a packet, a data stream, sensor data, a file, or other data. For example, the device 1440 can include one or more electric or electronic components that produce an electrical response to a stimulus. In another example, the device 1440 can include software to receives a stimulus and produces a response to the stimulus.

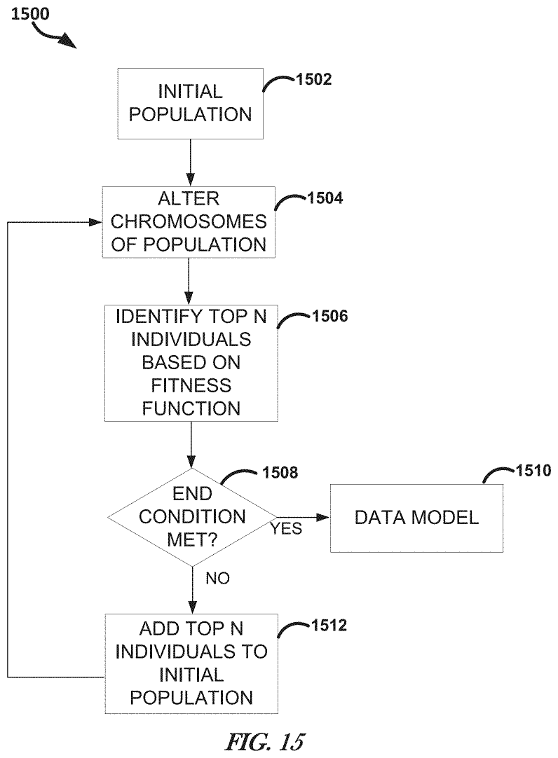

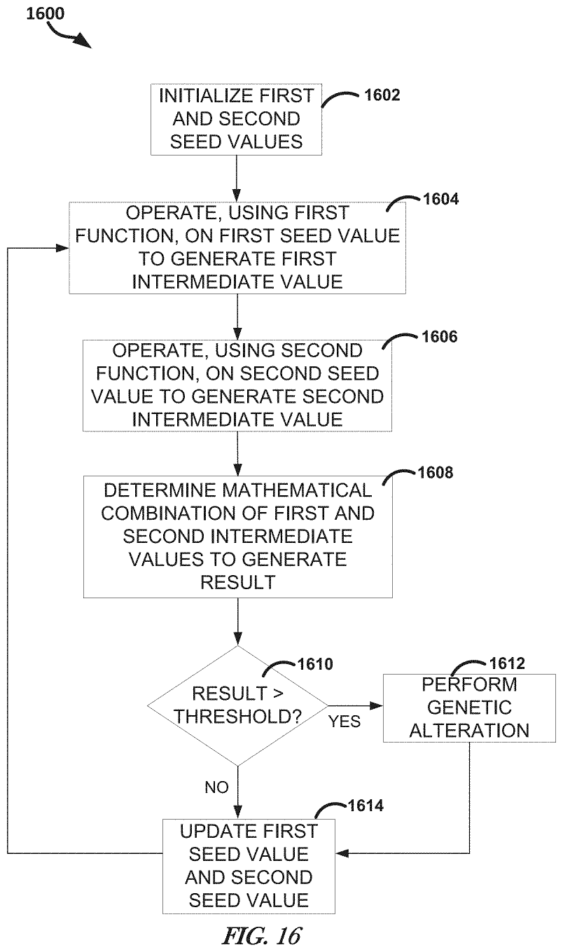

The operation 108 can include receiving the measurement 1440 and generating a model 1442 based on the measurement 1440. The model 1442 can be determined using a GEP technique. More details regarding embodiments of the model are provided regarding FIGS. 15-16.

FIG. 15 illustrates, by way of example, a diagram of an embodiment of a GEP modeling method 1500. The method 1500 as illustrated includes generating or retrieving an initial population, at operation 1502. The initial population comprises entities with genomes comprised of chromosomes. Each of the chromosomes comprises one more variables, operators, or a combination thereof. A variable is an element that can change value. In the expression A*x+B*y=C, x and y are variables. The operator is a symbol that denotes an operation. In the previous expression, * (indicating multiplication) and + (indicating summation) are operators.

At operation 1504, one or more chromosomes of an entity of the population can be altered. Altering can include mutation, transposition, insertion, recombination, or a combination thereof. Mutation includes altering a portion of a chromosome to another variable or operator. Note that an operator can be replaced with only another operator and a variable can be replaced with either an operator or a variable. Transposition includes movement of a portion of a chromosome to another spot in the chromosome. The transposition can be constrained to include one or more operators and corresponding variables. Insertion includes adding one or more operators or variables to the chromosome. Recombination includes exchanging entities between two chromosomes. Consider the following binary sequences {001000000} and {101000011}. A recombination of the sequences can include exchanging the first four entities of the sequences to generate the following progeny {101000000} and {001000011}. Note that, for each altered entity, a parent (an entity whose genetic material was altered to generate the altered entity) can be removed or remain. By removing the parent and retaining the altered entity (sometimes called a child or progeny), a population can remain a same size. By retaining the parent, the population can grow.

In performing each alteration, prior GEP techniques use a random number generator. The random number generator is used to generate a value. The value generated dictates whether an alteration occurs and can even dictate the specific alteration that occurs. Drawbacks with prior random number generators include time and memory constraints. Using a sincos function gets rid of a pseudorandom number generator process and replaces it with a function. The function consumes less memory space and reduces computations and memory accesses. Instead of using a prior random number generator, embodiments can use a mathematical combination of orthogonal, sometimes cyclic, functions to generate a value. The value can be used in place of a value generated by the random number generator. More details regarding generating the value and performing the alteration are described regarding FIG. 16.

At operation 1506, the top N individuals of the population can be identified based on a fitness function. N can be an integer greater than or equal to 1. The top N individuals are the individuals in the population that (alone or in combination) best satisfy a fitness function. The fitness function, in embodiments, can include an ability to explain the measurement 1442 of the device 1440. The fitness function can include an error (root mean square error, covariance, or the like) that indicates a difference between the top N individuals and the measurement 1442. An error of zero, means that the top N individuals perfectly explain the measurement 1442. This error may not be attainable in all cases.

At operation 1508, it can be determined if an end condition is met. The end condition can include the error being below a threshold.

If the end condition is met, as determined at operation 1508, the data model can be provided at operation 1510. The data model can include a combination of one or more of the top N individuals. If the end condition is not met, as determined at operation 1508, the top N individuals can be added to the initial population at operation 1512. The top N individuals can replace the top N individuals from a previous iteration (to keep the size of the population static) or can be added along with the previous top N individuals (to grow the population). Growing the population can require more processing operations per iteration than keeping the population static. The operation 1504 can be performed after the operation 1512.

FIG. 16 illustrates, by way of example, a diagram of an embodiment of a method 1600 for determining a value that governs genetic alteration. The method 1600 includes initializing first and second seed values 1602. The first and second seed values 1602 can be chosen to make the result of the sincos function produce results that are uniformly distributed. However, other values can be chosen for either of these seed values.

At operation 1604, a first function can be used on the first seed value to generate a first intermediate value. The first function can include a cyclic function, periodic function, or the like. A cyclic function is one that produces a same output for different input. A periodic function is a special case of a cyclic function that repeats a series of output values for different input values. Examples of periodic functions include sine, cosine, or the like. In some embodiments, the first seed value can be raised to a power before being input into the first function. The power can be any value, such as an integer, fraction, transcendental number, or the like.

At operation 1606, a second function can operate on the second seed value to generate a second intermediate value. The second function can be orthogonal to the first function. In some embodiments, the second seed value can be raised to a power before being input into the first function. The power can be any value, such as an integer, fraction, transcendental number, or the like. Using a transcendental number can increase memory or processing overhead but can produce results that are more random than a fraction or integer.

At operation 1608, the first intermediate value and the second intermediate value can be mathematically combined to generate a result. The mathematical combination can include weighting either the first intermediate value or the second intermediate value. In some embodiments, the weighting can constrain the result to a specified range of values (e.g., [min, max]). For example, to constrain the result in which the first function is a sine function, the second function is a cosine function, and the mathematical combination is addition, the weighting can include division by two. The mathematical combination can include an addition, multiplication, division, subtraction, logarithm, exponential, integration, differentiation, transform, or the like. The mathematical combination can include adding a constant to shift the range of values to be more positive or more negative.

In mathematical terms, the following equation summarizes the function used to produce the result:

Result=a*firstfunction((seed1)^{x})▪b*(secondfunction((seed2)^{y})+c

Where ▪ indicates one or more mathematical operations to perform the mathematical combination, a and b are the weights, x and y are the powers, and c is the constant (e.g., an integer or real number).

At operation 1610, it can be determined whether the result is greater than, or equal to, a threshold. The threshold can be the same or different for different alterations or individuals. In some embodiments, the threshold can change based on an iteration number (the number of iterations performed). In some embodiments, the threshold can change based on how close the top N individuals are to satisfying the end condition (as determined at operation 1508, see FIG. 15). In some embodiments, the closer the top N individuals are to satisfying the end condition, the higher the threshold can be set. The threshold can be set to control a rate of evolution of the population. A lower threshold can increase the rate of evolution while a higher threshold can decrease the rate of evolution.

In response to determining the result is greater than the threshold at operation 1610, a genetic alteration can be performed at operation 1612. The operation 1612 is a subset of the operations performed at operation 1504.

In response to determining the result is not greater than the threshold at operation 1610, the first and second seed values can be updated at operation 1614. Updating the first and second seed values can include adding an offset to the first value and the second value. The offset can be the same or different for each of the first and second seed values. In some embodiments, the offset can be determined using the first function or the second function. In some embodiments, the first seed can be input to the first function to determine a first offset and the second seed can be input to the second function to determine a second offset. The first offset can then be added to the first seed value to generate an updated first seed value. The second offset can then be added to the second seed value to generate an updated second seed value. In some embodiments, the inputs to the function that defines the offset can be raised to a power, similar to the power used to generate the intermediate value at operation 1604, 1606 in some embodiments. In mathematical terms the seed update is summarized as follows:

Updated Seed=a*previous_seed▪b*offset+c

Where ▪ indicates one or more mathematical operations to perform the mathematical combination, a and b are weights (same or different weights previously discussed), and c is a constant (same or different as that previously discussed). The updated seed values can then be used to determine a next result by iterating through method 1600 starting at operation 1604.

FIG. 17 illustrates, by way of example, a graph of model predictions and a variable to be predicted by the model. The model prediction is provided by line 1770 and a variable value is provided by line 1772. The behavior in the region 1774 is not predicted by the model. The error between the model prediction and the measurements of the measurement corpus 102 is greater than a threshold value. A different model can be generated to explain the device behavior in the region 1774 or more measurements can be gathered and added to the measurement corpus 102 and a new model can be generated to better explain the behavior of the device or system.

FIG. 18 illustrates, by way of example, a diagram of an embodiment of a graph of a sampled model. The graph indicates the boundaries of the model, as defined by the min of variable 1 and variable 2 1884, max of variable 2 1886, and max of variable 1 1882. The boundary can be defined, at least in part, by the minimum and maximum values of the variable in the measurement corpus 102. Within the boundary, the model is valid in some regions 1888, and invalid in other regions 1890. The invalid regions are regions within the boundary for which there is insufficient data to make a prediction or regions in which the device or system does not operate. Further measurements can be gathered to help explain the invalid regions of concern (in areas in which the device or system is expected to operate).

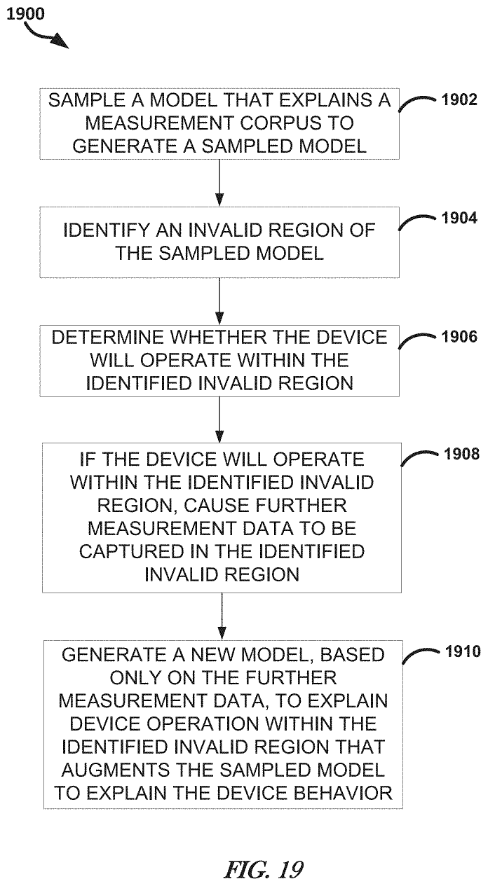

FIG. 19 illustrates, by way of example, a diagram of an embodiment of a method 1900 for an alternative to DOE. The method 1900 as illustrated includes sampling a model that explains a measurement corpus of measurement data to generate a sampled model, at operation 1902; identifying an invalid region of the sampled model, at operation 1904; determining whether a device will operate within the identified invalid region, at operation 1906; if the device will operate within the identified invalid region, causing further measurement data to be captured in the identified invalid region, at operation 1908; and generating a new model, based only on the further measurement data, to explain device operation within the identified invalid region that augments the sampled model to explain the device behavior, at operation 1910. The method can further include generating a polynomial model or a gene expression model, the model, for the measurement corpus. The method 1900 can further include, wherein the model has a specificity and a sensitivity of one (1).

The method 1900 can further include identifying boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model. The method 1900 can further include reducing an amount of data used to generate the model by identifying minimum relevant data of the measurement corpus by spatial voting the measurement corpus to a defined grid of cells. The method 1900 can further include, wherein identifying the minimum relevant data further includes generating synthetic data for data that maps to same cell of the grid of cells. The method 1900 can further include, wherein the device does not currently exist and the measurement corpus is from one or more sensors of prior devices.

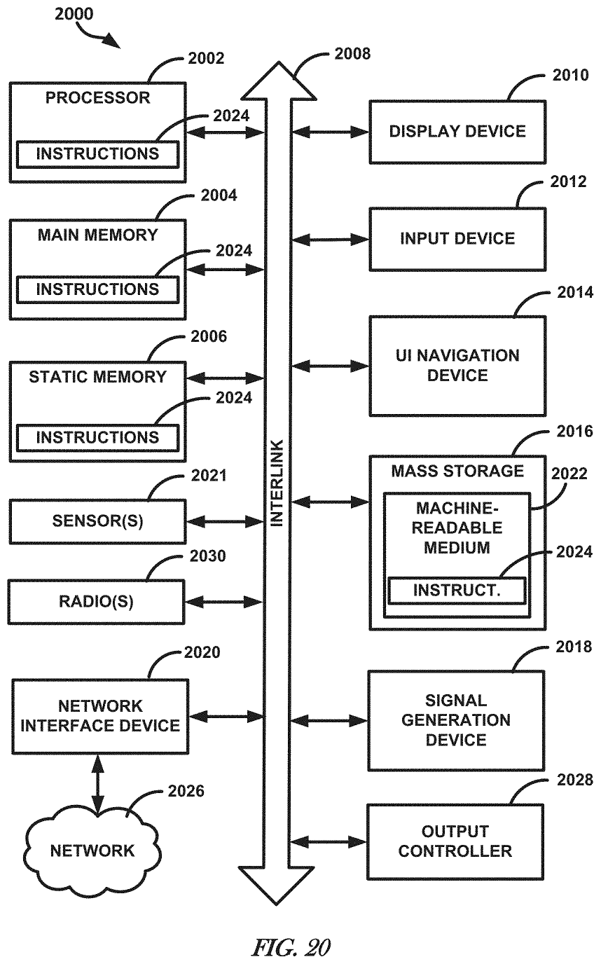

FIG. 20 illustrates, by way of example, a block diagram of an embodiment of a machine 2000 on which one or more of the methods, such as those discussed about FIGS. 1-19 and elsewhere herein can be implemented. In one or more embodiments, one or more items of the system 200, 500, 600, 1400 can be implemented by the machine 1400. In alternative embodiments, the machine 2000 operates as a standalone device or may be connected (e.g., networked) to other machines. In a networked deployment, the machine 2000 may operate in the capacity of a server or a client machine in server-client network environment, or as a peer machine in a peer-to-peer (or distributed) network environment. The machine 2000 may be a personal computer (PC), a tablet PC, a set-top box (STB), a Personal Digital Assistant (PDA), a cellular telephone, a web appliance, a network router, switch or bridge, embedded computer or hardware, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example machine 2000 includes processing circuitry 2002 (e.g., a hardware processor, such as can include a central processing unit (CPU), a graphics processing unit (GPU), an application specific integrated circuit, circuitry, such as one or more transistors, resistors, capacitors, inductors, diodes, logic gates, multiplexers, oscillators, buffers, modulators, regulators, amplifiers, demodulators, or radios (e.g., transmit circuitry or receive circuitry or transceiver circuitry, such as RF or other electromagnetic, optical, audio, non-audible acoustic, or the like), sensors 2021 (e.g., a transducer that converts one form of energy (e.g., light, heat, electrical, mechanical, or other energy) to another form of energy), or the like, or a combination thereof), a main memory 2004 and a static memory 2006, which communicate with each other and all other elements of machine 2000 via a bus 2008. The transmit circuitry or receive circuitry can include one or more antennas, oscillators, modulators, regulators, amplifiers, demodulators, optical receivers or transmitters, acoustic receivers (e.g., microphones) or transmitters (e.g., speakers) or the like. The RF transmit circuitry can be configured to produce energy at a specified primary frequency to include a specified harmonic frequency.

The machine 2000 (e.g., computer system) may further include a video display unit 2010 (e.g., a liquid crystal display (LCD) or a cathode ray tube (CRT)). The machine 2000 also includes an alphanumeric input device 2012 (e.g., a keyboard), a user interface (UI) navigation device 2014 (e.g., a mouse), a disk drive or mass storage unit 2016, a signal generation device 2018 (e.g., a speaker) and a network interface device 2020.

The mass storage unit 2016 includes a machine-readable medium 2022 on which is stored one or more sets of instructions and data structures (e.g., software) 2024 embodying or utilized by any one or more of the methodologies or functions described herein. The instructions 2024 may also reside, completely or at least partially, within the main memory 2004 and/or within the processing circuitry 2002 during execution thereof by the machine 2000, the main memory 2004 and the processing circuitry 2002 also constituting machine-readable media. One or more of the main memory 2004, the mass storage unit 2016, or other memory device can store the data for executing a method discussed herein.

The machine 2000 as illustrated includes an output controller 2028. The output controller 2028 manages data flow to/from the machine 2000. The output controller 2028 is sometimes called a device controller, with software that directly interacts with the output controller 2028 being called a device driver.

While the machine-readable medium 2022 is shown in an example embodiment to be a single medium, the term “machine-readable medium” may include a single medium or multiple media (e.g., a centralized or distributed database, and/or associated caches and servers) that store the one or more instructions or data structures. The term “machine-readable medium” shall also be taken to include any tangible medium that can store, encode or carry instructions for execution by the machine and that cause the machine to perform any one or more of the methodologies of the present invention, or that can store, encode or carry data structures utilized by or associated with such instructions. The term “machine-readable medium” shall accordingly be taken to include, but not be limited to, solid-state memories, and optical and magnetic media. Specific examples of machine-readable media include non-volatile memory, including by way of example semiconductor memory devices, e.g., Erasable Programmable Read-Only Memory (EPROM), Electrically Erasable Programmable Read-Only Memory (EEPROM), and flash memory devices; magnetic disks such as internal hard disks and removable disks; magneto-optical disks; and CD-ROM and DVD-ROM disks.

The instructions 2024 may further be transmitted or received over a communications network 2026 using a transmission medium. The instructions 2024 may be transmitted using the network interface device 2020 and any one of several well-known transfer protocols (e.g., hypertext transfer protocol (HTTP), user datagram protocol (UDP), transmission control protocol (TCP)/internet protocol (IP)). The network 2026 can include a point-to-point link using a serial protocol, or other well-known transfer protocol. Examples of communication networks include a local area network (“LAN”), a wide area network (“WAN”), the Internet, mobile telephone networks, Plain Old Telephone (POTS) networks, and wireless data networks (e.g., WiFi and WiMax networks). The term “transmission medium” shall be taken to include any intangible medium that can store, encode or carry instructions for execution by the machine, and includes digital or analog communications signals or other intangible media to facilitate communication of such software.

This disclosure can be understood with a description of some embodiments, sometimes called examples.

Example 1 can include a system for device analysis, the system comprising a memory including a measurement corpus from prior devices stored thereon, processing circuitry coupled to the memory, the processing circuitry being configured to sample a model that explains the measurement corpus to generate a sampled model, identify an invalid region of the sampled model, determine whether the device will operate within the identified invalid region, if the device will operate within the identified invalid region, cause further measurement data to be captured in the identified invalid region, and generate a new model, based only on the further measurement data, to explain device operation within the identified invalid region that augments the sampled model to explain the device behavior.

In Example 2, Example 1 can further include, wherein the processing circuitry is further configured to generate a polynomial model or a gene expression model, the model, for the measurement corpus.

In Example 3, Example 2 can further include, wherein the model has a specificity and a sensitivity of one (1).

In Example 4, at least one of Examples 1-3 can further include, wherein the processing circuitry is further to identify boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

In Example 5, at least one of Examples 1-4 can further include, wherein the processing circuitry is further configured to reduce an amount of data used to generate the model by identifying minimum relevant data of the measurement corpus by spatial voting the measurement corpus to a defined grid of cells.

In Example 6, Example 5 can further include, wherein identifying the minimum relevant data further includes generating synthetic data for data that maps to same cell of the grid of cells.

In Example 7, at least one of Examples 1-6 can further include, wherein the device does not currently exist and the measurement corpus is from one or more sensors of prior devices.

Example 8 includes a non-transitory machine-readable medium including instructions that, when executed by a machine, cause the machine to perform operations for device analysis, the operations comprising sampling a model that explains a measurement corpus of measurement data to generate a sampled model, identifying an invalid region of the sampled model, determining whether a device will operate within the identified invalid region, if the device will operate within the identified invalid region, causing further measurement data to be captured in the identified invalid region, and generating a new model, based only on the further measurement data, to explain device operation within the identified invalid region that augments the sampled model to explain the device behavior.

In Example 9, Example 8 can further include, wherein the operations further include generating a polynomial model or a gene expression model, the model, for the measurement corpus.

In Example 10, Example 9 can further include, wherein the model has a specificity and a sensitivity of one (1).

In Example 11, at least one of Examples 8-10 can further include, wherein the operations further include identifying boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

In Example 12, at least one of Examples 8-11 can further include, wherein the operations further include reducing an amount of data used to generate the model by identifying minimum relevant data of the measurement corpus by spatial voting the measurement corpus to a defined grid of cells.

In Example 13, Example 12 can further include, wherein identifying the minimum relevant data further includes generating synthetic data for data that maps to same cell of the grid of cells.

In Example 14, at least one of Examples 8-13 can further include, wherein the device does not currently exist and the measurement corpus is from one or more sensors of prior devices.

Example 15 includes a computer-implemented method for device analysis, the method comprising sampling a model that explains a measurement corpus of measurement data to generate a sampled model, identifying an invalid region of the sampled model, determining whether a device will operate within the identified invalid region, if the device will operate within the identified invalid region, causing further measurement data to be captured in the identified invalid region, and generating a new model, based only on the further measurement data, to explain device operation within the identified invalid region that augments the sampled model to explain the device behavior.

In Example 16, Example 15 can further include, wherein the operations further include generating a polynomial model or a gene expression model, the model, for the measurement corpus.

In Example 17, Example 16 can further include, wherein the model has a specificity and a sensitivity of one (1).

In Example 18, at least one of Examples 15-17 can further include, wherein the operations further include identifying boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

In Example 19, at least one of Examples 15-18 can further include, wherein the operations further include reducing an amount of data used to generate the model by identifying minimum relevant data of the measurement corpus by spatial voting the measurement corpus to a defined grid of cells.

In Example 20, Example 19 can further include, wherein identifying the minimum relevant data further includes generating synthetic data for data that maps to same cell of the grid of cells.

In this document, the terms “a” or “an” are used, as is common in patent documents, to include one or more than one, independent of any other instances or usages of“at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

What is claimed is:

1. A system for device analysis, the system comprising:
a memory including a measurement corpus from prior devices stored thereon;
processing circuitry coupled to the memory, the processing circuitry being configured to:
sample a model that explains the measurement corpus to generate a sampled model;
identify an invalid region of the sampled model;
determine whether the device will operate within the identified invalid region;
if the device will operate within the identified invalid region, cause further measurement data to be captured in the identified invalid region; and
generate a new model, based only on the further measurement data, to explain device operation within the identified invalid region that augments the sampled model to explain the device behavior.

2. The system of claim 1, wherein the processing circuitry is further configured to generate a polynomial model or a gene expression model, the model, for the measurement corpus.

3. The system of claim 2, wherein the model has a specificity and a sensitivity of one (1).

4. The system of claim 1, wherein the processing circuitry is further to identify boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

5. The system of claim 1, wherein the processing circuitry is further configured to:
reduce an amount of data used to generate the model by identifying minimum relevant data of the measurement corpus by spatial voting the measurement corpus to a defined grid of cells.

6. The system of claim 5, wherein identifying the minimum relevant data further includes generating synthetic data for data that maps to same cell of the grid of cells.

7. The system of claim 1, wherein the device does not currently exist and the measurement corpus is from one or more sensors of prior devices.

8. A non-transitory machine-readable medium including instructions that, when executed by a machine, cause the machine to perform operations for device analysis, the operations comprising:
sampling a model that explains a measurement corpus of measurement data to generate a sampled model;
identifying an invalid region of the sampled model;
determining whether a device will operate within the identified invalid region;
if the device will operate within the identified invalid region, causing further measurement data to be captured in the identified invalid region; and
generating a new model, based only on the further measurement data, to explain device operation within the identified invalid region that augments the sampled model to explain the device behavior.

9. The non-transitory machine-readable medium of claim 8, wherein the operations further include generating a polynomial model or a gene expression model, the model, for the measurement corpus.

10. The non-transitory machine-readable medium of claim 9, wherein the model has a specificity and a sensitivity of one (1).

11. The non-transitory machine-readable medium of claim 8, wherein the operations further include identifying boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

12. The non-transitory machine-readable medium of claim 8, wherein the operations further include reducing an amount of data used to generate the model by identifying minimum relevant data of the measurement corpus by spatial voting the measurement corpus to a defined grid of cells.

13. The non-transitory machine-readable medium of claim 12, wherein identifying the minimum relevant data further includes generating synthetic data for data that maps to same cell of the grid of cells.

14. The non-transitory machine-readable medium of claim 8, wherein the device does not currently exist and the measurement corpus is from one or more sensors of prior devices.

15. A computer-implemented method for device analysis, the method comprising:
sampling a model that explains a measurement corpus of measurement data to generate a sampled model;
identifying an invalid region of the sampled model;
determining whether a device will operate within the identified invalid region;
if the device will operate within the identified invalid region, causing further measurement data to be captured in the identified invalid region; and
generating a new model, based only on the further measurement data, to explain device operation within the identified invalid region that augments the sampled model to explain the device behavior.

16. The method of claim 15, wherein the operations further include generating a polynomial model or a gene expression model, the model, for the measurement corpus.

17. The method of claim 16, wherein the model has a specificity and a sensitivity of one (1).

18. The method of claim 15, wherein the operations further include identifying boundaries of the sampled model, determine whether the device will operate at the determined boundaries and (a) if the device will operate at the identified boundaries, generate a new model, based on further measurement data at or within a specified percent value of the boundaries at which the device will operate and the measurement corpus, to replace the sampled model.

19. The method of claim 15, wherein the operations further include reducing an amount of data used to generate the model by identifying minimum relevant data of the measurement corpus by spatial voting the measurement corpus to a defined grid of cells.

20. The method of claim 18, wherein identifying the minimum relevant data further includes generating synthetic data for data that maps to same cell of the grid of cells.
